(19) United States
(12) Patent Application Publication
(10) Pub. No.: US 2010/0059808 A1
(43) Pub. Date: Mar. 11, 2010

(54) NONVOLATILE MEMORIES WITH CHARGE TRAPPING DIELECTRIC MODIFIED AT THE EDGES

(76) Inventors: Wei Zheng, Los Gatos, CA (US); Chung Wah Fon, Mountain View, CA (US)

Correspondence Address: Haynes and Boone, LLP;IP Section, 2323 Victory Avenue, SUITE 700, Dallas, TX, 75219, US

(21) Appl. No.: 12/208,133

(22) Filed: Sep. 10, 2008

(51) Int. Cl. H01L 29/00; H01L 21/3205

(52) U.S. Cl. 257/321; 438/594; 257/E29.001; 257/E21.294

(57) ABSTRACT

A nonvolatile memory cell has charge trapping dielectric (160) which has been modified (i.e. oxidized) adjacent to edges of blocking dielectric (180). The modification reduces the charge-trapping density adjacent to the edges of the blocking dielectric, and hence reduces the leakage current at the edges. Other features are also provided.

### BACKGROUND OF THE INVENTION

The present invention relates to charge-trapping memories.

The state of a charge-trapping memory cell is defined by the electric charge stored in the cell's charge-trapping dielectric (e.g. silicon nitride). The charge-trapping dielectric is positioned between the cell's active area (a semiconductor area including the cell's channel and source/drain regions) and the control gate. The charge-trapping dielectric is insulated from the active area by tunnel dielectric (e.g. silicon dioxide). The memory state can be changed by electron transfer between the charge-trapping dielectric and the active area through the tunnel dielectric. For example, to program the memory cell, a positive voltage is applied to the control gate relative to the channel region to transfer electrons from the active area to the charge-trapping dielectric. To erase the memory cell, a negative voltage is applied to transfer electrons back to the active area.

When electrons are being transferred from the active area to the charge-trapping dielectric, electrons should be prevented from moving from the charge-trapping dielectric to the control gate. Likewise, when the memory is being erased, electrons should be blocked from moving from the control gate to the charge-trapping dielectric. For this purpose, blocking dielectric (e.g. silicon dioxide or aluminum oxide) is provided between the charge-trapping dielectric and the control gate.

The insulating property of the blocking dielectric can be weakened at the edges by defects created when the blocking dielectric is patterned. The resulting current leakage at the edges of the blocking dielectric makes it more difficult to control the state of the cell by the program and erase processes described above, and the charge leakage reduces the data retention time. The leakage can be reduced by increasing the distance between the control gate and the edges of the blocking dielectric. More particularly, the following manufacturing process has been proposed. First, layers are formed that will provide the tunnel dielectric, the charge-trapping dielectric, the blocking dielectric, and the control gate. Then the control gate is patterned. Then dielectric spacers are formed on the control gate's sidewalls. The control gate and the spacers are used to pattern the blocking dielectric. The spacers cause the blocking dielectric edges to protrude farther outward relative to the control gate edges, thus increasing the resistance of the current path between the blocking dielectric's edges and the control gate.

### SUMMARY

This section summarizes some features of the invention. Other features may be described in the subsequent sections. The invention is defined by the appended claims, which are incorporated into this section by reference.

The inventors have discovered, and experimentally confirmed, that the current leakage through the blocking dielectric edges can be reduced by modifying the composition of the charge-trapping dielectric at the edges adjacent to the edges of the blocking dielectric. For example, in some embodiments, the charge-trapping dielectric is formed of silicon-rich silicon nitride (“SiRN” hereinbelow). After the charge-trapping dielectric and the blocking dielectric have been patterned, the wafer is oxidized. Therefore, the edge portions of the charge-trapping dielectric are converted to silicon oxide and/or silicon oxynitride (SION). The oxidation reduces the density of the charge trapping sites at the edges of the charge trapping dielectric and hence reduces the conductivity of charges at the edges, thus reducing the charge and current leakage through the blocking dielectric edges (and through the tunnel dielectric edges).

Silicon-rich silicon nitride advantageously provides a higher density of charge-trapping sites than stoichiometric silicon nitride (Si₃N₄). The high density of trapping sites allows one to reduce the programming and erase times and/or the programming and erase voltages and to facilitate differentiation between memory states in the reading operation. However, the high density of trapping sites may increase the leakage current, making it particularly important that the leakage current be reduced. Further, in some dielectrics including aluminum oxide, the etch damage cannot be effectively annealed by heating, so reducing the edge leakage via modifying the charge-trapping dielectric is particularly appropriate.

Some embodiments include spacers over the control gate's edges over the blocking dielectric.

The invention is not limited to such spacers, to the silicon rich silicon nitride, or other features or advantages described above except as defined by the appended claims.

### BRIEF DESCRIPTION OF THE DRAWINGS

FIG. 1A shows a vertical cross section of a nonvolatile memory array in the process of fabrication according to some embodiments of the present invention.

FIG. 1B is a top view of some features of the structure of FIG. 1A.

FIG. 2A shows a vertical cross section of a nonvolatile memory array in the process of fabrication according to some embodiments of the present invention.

FIG. 2B is a top view of some features of the structure of FIG. 1A.

FIG. 3A shows a vertical cross section of a nonvolatile memory array in the process of fabrication according to some embodiments of the present invention.

FIG. 3B is a top view of some features of the structure of FIG. 1A.

FIG. 4A shows a vertical cross section of a nonvolatile memory array in the process of fabrication according to some embodiments of the present invention.

FIG. 4B is a top view of some features of the structure of FIG. 1A.

FIG. 5A illustrates experimental data illustrating some features of some embodiments of the present invention.

FIG. 5B is a top view of some features of some test structures used to obtain the data of FIG. 5A.

### DESCRIPTION OF SOME EMBODIMENTS

The embodiments described in this section illustrate but do not limit the invention except as defined by the appended claims. In particular, the materials and dimensions given in this section are for illustration purposes only except as defined by the appended claims.

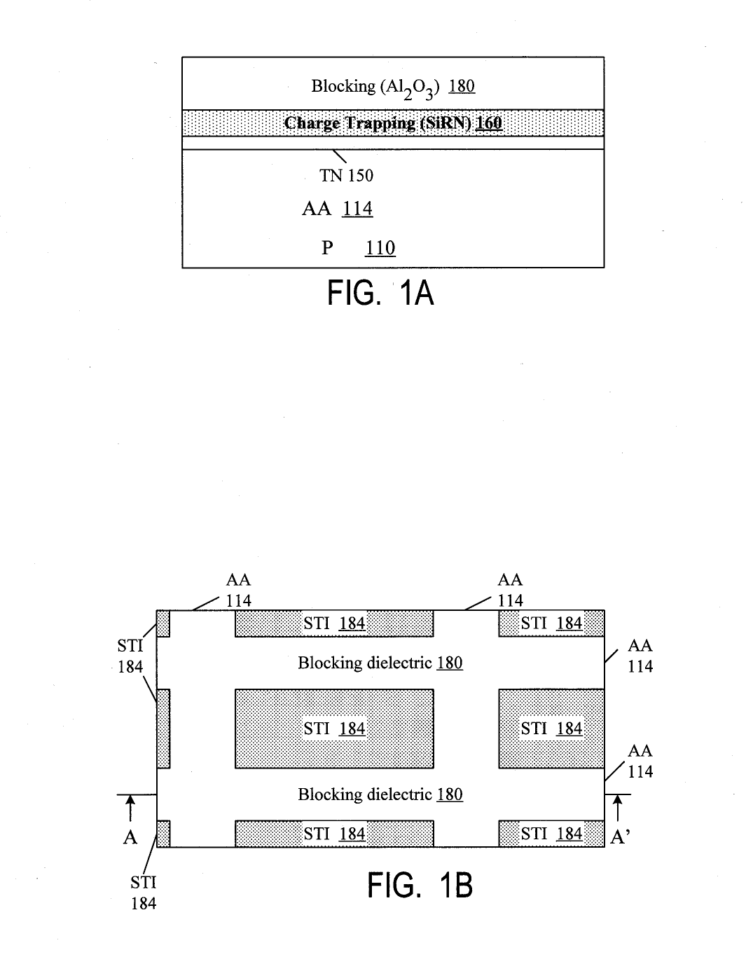

FIGS. 1A, 1B illustrates the beginning stages of fabrication of an array of memory cells which incorporate an embodiment of the present invention. The invention is not limited to an array or a particular array or cell architecture, and may include a single memory cell or any combination of such cells. FIG. 1A shows a vertical cross section along the line A-A′ shown in the top view FIG. 1B. FIGS. 1A, 1B are not drawn to the same scale. As shown in FIG. 1A, an isolated P well is formed in monocrystalline silicon substrate 110. The P well will include the memory cell's active area 114. Tunnel dielectric 150 is formed on the active area 114. In some exemplary, non-limiting embodiments, dielectric 150 is silicon dioxide thermally grown to a thickness of 4 nm.

Charge trapping dielectric 160 is deposited on tunnel dielectric 150. In some embodiments, charge trapping dielectric 160 is silicon-rich silicon nitride (“SiRN”, Si_{X}N_{y}, x:y>3:4) formed by chemical vapor deposition (CVD) to a thickness of 8 nm. The atomic ratio x:y of silicon to nitrogen can be controlled by controlling the ratio of the flow rates of the gaseous species which provide the silicon and nitrogen atoms for the CVD reaction. In some embodiments, the x:y ratio is approximately 1:1.

Blocking dielectric 180 is deposited on the wafer. In some embodiments, blocking dielectric 180 is aluminum oxide deposited to 15 nm thickness by atomic layer deposition.

If desired, the structure can be patterned at this stage to form shallow trench isolation regions (STI regions) 184 to isolate the active areas 114 of adjacent memory cells from each other. For example, a hard mask (not shown) can be formed, and the layers 180, 160, 150 and substrate 110 can be etched to form the STI trenches in the substrate. The trenches can be filled with dielectric 184, e.g. silicon dioxide, which initially covers the structure but then is planarized (e.g. by an etch and/or chemical-mechanical polishing (CMP)) to provide a top surface coplanar with the planar top surface of blocking dielectric 180. See e.g. U.S. patent application Ser. No. 11/113,509 filed on Apr. 25, 2005 by Shiraiwa et al. and published as no. 2006/0240635 A1 on Oct. 26, 2006, incorporated herein by reference. If desired, trench dielectric 184 can be etched down below the top surface of blocking dielectric 180.

Alternatively, the STI isolation can be formed before deposition of tunnel dielectric 150. The STI dielectric 184 can protrude above the substrate 110. Then tunnel dielectric 150 can be formed (by thermal oxidation for example). Then charge trapping dielectric 160 can be deposited to fill the spaces between STI regions 184 and etched down to have a top surface below the top surface of the STI dielectric 184. Blocking dielectric 180 can be deposited to fill the spaces between STI regions 184 and can be etched down or polished so that its top surface is level with the top surface of the STI dielectric 184. These details are not limiting. The invention is not limited to a particular type or geometry of substrate isolation. For example, the isolation can be formed by LOCOS, pn junctions, and/or possibly other techniques, or substrate isolation can be omitted depending on a particular application.

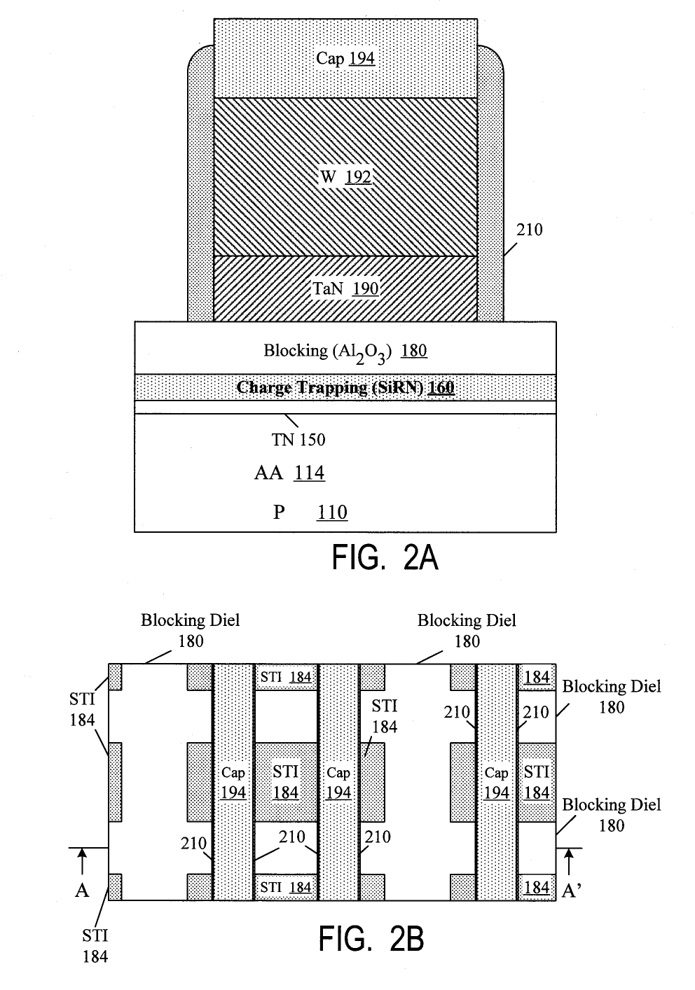

FIGS. 2A, 2B illustrate subsequent fabrication steps. FIG. 2B is a top view, and FIG. 2A shows the vertical cross section by the same plane A-A′ as marked in FIG. 1B (and also in FIG. 2B). A conductive layer is deposited on the wafer to provide control gates for the memory array. In some embodiments, the conductive layer consists of a bottom layer 190 of tantalum nitride (exemplary thickness is 20 nm) and a top layer 192 of tungsten (exemplary thickness 50 nm). Then cap layer 194 (e.g. silicon dioxide) is deposited and patterned to provide a hard mask for a subsequent etch. This etch removes the exposed portions of conductive layers 192 and 190, stopping on blocking dielectric 180 and, possibly, on the STI dielectric 184. The etch forms a number of stacks of layers 190, 192, 194. Each stack runs across the memory array in the wordline direction and provides control gates to one row of memory cells. Each field region 184 underlies two adjacent stacks.

Spacers 210 are formed on these stacks' sidewalls. In some embodiments, the spacers are formed of silicon nitride and are 10 nm wide at the bottom. The spacers can be formed without a photolithography by a conformal deposition and anisotropic etch of a silicon nitride layer. The etch can be selective to blocking dielectric 180 and STI dielectric 184. The spacers are not formed elsewhere in the memory array if the top surface of STI regions 184 is coplanar with the top surface of blocking dielectric 180 or if the difference in height between the adjacent top surfaces is small. The invention is not limited to such embodiments however.

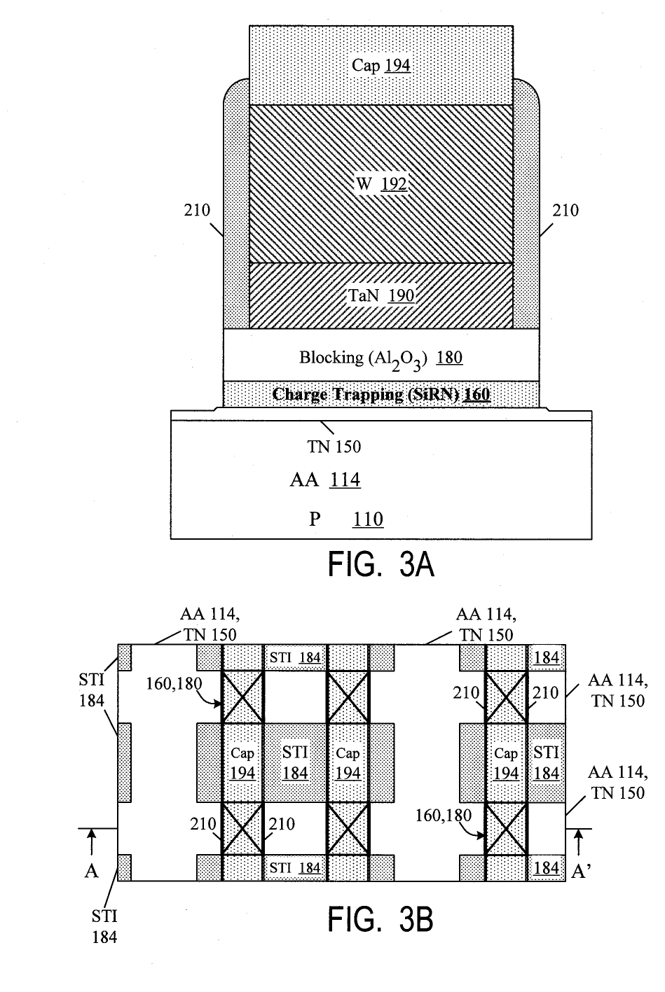

FIGS. 3A, 3B illustrate the subsequent etch of blocking dielectric 180 and charge trapping dielectric 160. FIG. 3B is a top view, and FIG. 3A shows the vertical cross section by the same plane A-A′ as marked in FIGS. 1B and 2B (and also in FIG. 3B). The etching processes are anisotropic. Cap layer 194 and nitride spacers 210 serve as a mask. No photolithographic masking is used in the memory array area. The etch of silicon nitride 160 slightly reduces the height of silicon nitride spacers 210. The etch is selective to silicon dioxide, but some of oxide 150 and 194 may be removed. In some embodiments, the etch removes all of the exposed portions of oxide 150. The charge trapping dielectric 160 and the blocking dielectric 180 remain over the active areas under the cap layer 194 and spacers 210 at the locations shown with crosses in FIG. 3B.

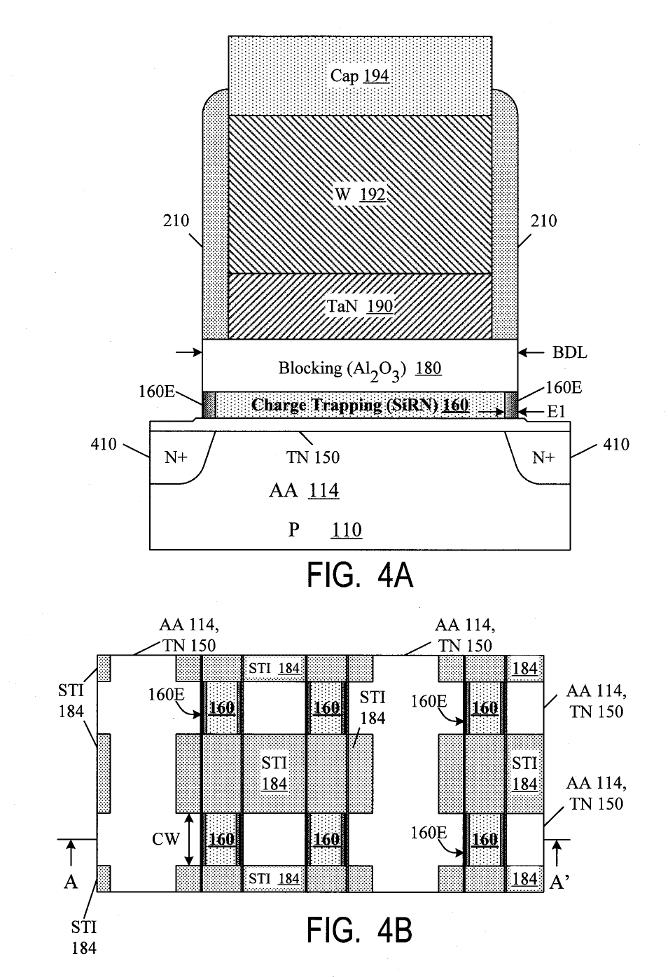

FIGS. 4A, 4B illustrate the subsequent oxidation to modify the composition of charge-trapping dielectric 160 in the edge regions 160E. FIG. 4B is the top view without layers 194, 192, 190, 180. FIG. 4A shows the vertical cross section by the same plane A-A′ as marked in FIGS. 1B, 2B, and 3B (and also 4B). The edge regions 160E can be of any suitable length E1, e.g. 4 nm or greater. In the oxidation process, oxygen diffuses laterally by up to the distance E1 into charge-trapping dielectric 160 and binds with silicon and/or nitrogen to form silicon oxide and/or silicon oxynitride, thus reducing the charge trapping density in the edge regions 160E. The edge regions 160E can be defined as (i) regions in which the atomic oxygen concentration is more than 30%, or (ii) as regions in which the atomic nitrogen concentration is less than 30%, or (iii) as regions in which both (i) and (ii) are true. In some embodiments, E1=4 nm to 12 nm; the entire length BDW of charge trapping dielectric 160 (and hence of blocking dielectric 180) is 50 nm (this is roughly the channel length of the memory cell); the channel width CW (FIG. 4B) is 70 nm; the thicknesses of silicon dioxide 150, silicon-rich silicon nitride 160, and aluminum oxide 180 are respectively 4 nm, 8 nm, and 15 nm; the atomic ratio Si:N in nitride 160 is approximately 1:1 (the refractive index of nitride 160 is 2.1); the oxidation of edge regions 160E increases the combined effective oxide thickness (EOT) of layers 150, 160, 180 in one cell by about 3 nm.

In some embodiments, the outer boundary of edge regions 160E is entirely or almost entirely converted to silicon oxide. Thus, the atomic ratio O:N of oxygen to nitrogen is infinite or almost infinite at the outer boundary of edge regions 160E. The O:N ratio gradually decreases towards the inner boundary of regions 160E.

In some embodiments, the oxidation process is wet oxidation to provide a sharp drop of oxygen concentration at the inner boundary of edge regions 160E. The temperature and other parameters may vary depending on the materials for conductive layers 190, 192 to avoid damage (e.g. peel-off) to this layers. Note for example that an excessive temperature may cause tungsten to peel off. Some embodiments use ISSG (in-situ steam generation) at the temperature of 850° C. for one minute. Another suitable process is RTO (rapid thermal oxidation) performed at 900° C. for five minutes at atmospheric pressure in oxygen ambient. Still another suitable process is SELOX described, for example, in U.S. Pat. No. 7,078,313 B2 issued Jul. 18, 2006 to Kirchhoff and incorporated herein by reference. See also M. Ripley et al., “Selective Rapid Thermal Oxidation of Silicon vs. Tungsten using Oxygen in Hydrogen”, Advanced Thermal Processing of Semiconductors, 2007 (RTP 2007; 15^{th} International Conference, pages 215-221), incorporated herein by reference. The SELOX process time may be 120 minutes. This process involves low temperature oxidation of silicon in the presence of hydrogen. Hydrogen is used to avoid tungsten oxidation if tungsten is present and exposed. An exemplary temperature range is 400-950° C.

In these embodiments, the oxidation process does not oxidize the edges of charge-trapping dielectric 160 adjacent to STI regions 184 (except at the corners of these edges). Of note, if blocking dielectric 180 was deposited after the STI formation as described above, then the edges of blocking dielectric 180 adjacent to the STI regions were not etched when the blocking dielectric was patterned. Therefore, these edges are not subjected to the etching damage and are not as leaky as the edges adjacent to the edge regions 160E. In some embodiments however the charge trapping dielectric 160 is oxidized on all sides, including at the edges adjacent to STI regions 184. This can be done, for example, if the charge trapping dielectric 160 and the blocking dielectric 180 are patterned and subjected to oxidation before deposition of control gate layers 190, 192.

The remaining fabrication steps can be conventional. For example, a silicon nitride liner (not shown) can be deposited over the structure, and then an N+ implant can be conducted to form N+ doped source/drain regions 410 (FIG. 4A) in substrate 110. Additional dielectric layers and bitlines can be formed as needed. In some embodiments, the memory cell can be programmed by Fowler-Nordheim (FN) or direct tunneling of electrons from the cell's channel region and/or source/drain region or regions into the charge-trapping dielectric 160 as the channel and/or source/drain region or regions are provided with a negative voltage relative to control gate 190/192 (i.e. the wordline). The memory cell can be erased by the reverse tunneling as the channel and/or source/drain region or regions are provided with a positive voltage relative to control gate 190/192. The memory cell can be read by sensing the source or drain current when the cell's source/drain regions 410 are at different voltages and the control gate 190/192 is at a positive voltage relative to at least one of the source/drain regions. Alternatively, the memory cell can be programmed by hot electron injection and/or erased by hot hole injection. See e.g. U.S. patent application Ser. No. 11/131,006 filed May 17, 2005 by Bhattacharyya and published as no. 2006/0261401 A1 on Nov. 23, 2006; and U.S. Pat. No. 7,067,373 issued Jun. 27, 2006 to Shukuri, both incorporated herein by reference. The voltages for the memory operation are provided by suitable voltage generators. The invention is not limited to particular cell or arrays architectures or programming or erase methods. In some embodiments, the memory is programmed and/or erased by charge transfer between the charge trapping layer 160 and the control gate 190/192 through dielectric 180. The oxidized regions 160E reduce the leakage through the edges of dielectric 180 when neither programming nor erase are performed. Some embodiments are one-time programmable (non-erasable) memories. Further, the invention is not limited to stacked-gate memory cells. For example, control gate 190/192 may extend laterally beyond the charge-trapping dielectric 160 to overlap a source/drain region 410, or a separate select gate may be provided, to obtain split-gate architectures. A multi-bit memory cell can also be provided.

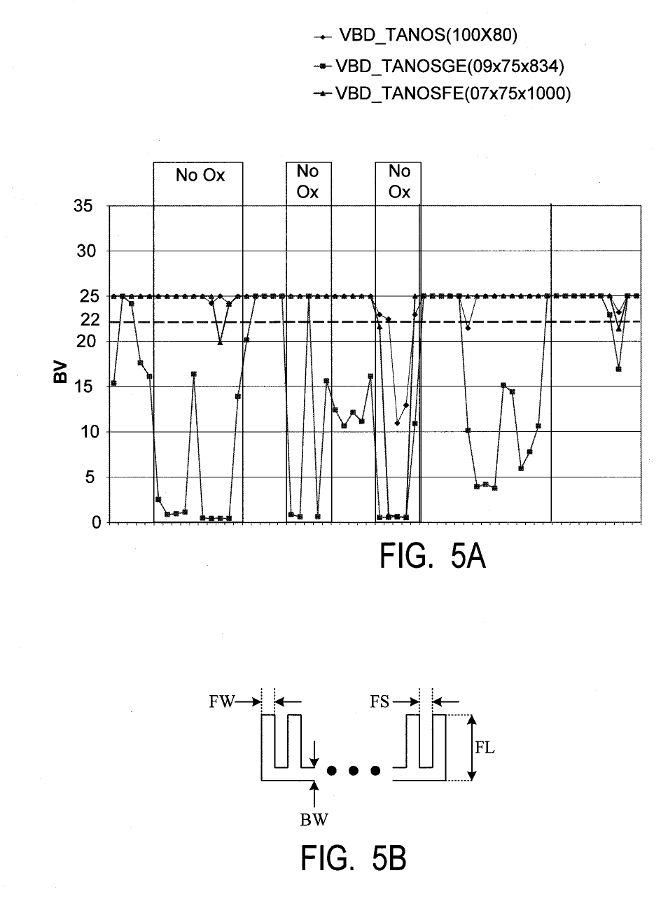

Oxidation of the charge trapping dielectric's edge regions 160E also increases the breakdown voltage of the cell. FIG. 5A shows pertinent experimental data. The data was obtained using a capacitor structure similar to that illustrated in FIG. 2A (but without spacers 210). The bottom plate of the capacitor was a P doped polysilicon layer with P type dopant concentration of 10¹⁶ atoms/cm³. This polysilicon layer was deposited over a dielectric. The polysilicon was thermally oxidized to grow silicon dioxide 150 (as in FIG. 2A) to a thickness of 50 nm. Then SiRN layer 160 was deposited to a thickness of 8 nm. The silicon to nitrogen atomic ratio Si:N was about 1:1. Then aluminum oxide 180 was deposited by atomic layer deposition (ALD) to a thickness of 15 nm. Then tantalum nitride 190 was deposited to a thickness of 20 nm. These layers were patterned and the breakdown voltage BV was measured and plotted along the vertical axis. The horizontal axis marks different capacitor structures (different test points).

The data points VBD_TANOS were obtained for the capacitors rectangular in top view, having the lateral dimensions of 100×80 μm. The data points VBD_TANOSGE were obtained for the capacitors with tantalum nitride 190 and aluminum oxide 180 patterned as a multi-finger structure shown in top view in FIG. 5B. The structure had 834 fingers each of which was 0.09 μm wide (FW=0.09 μm). The distance FS between the adjacent fingers was also 0.09 μm. The fingers were interconnected by a strip having the width BW=5 μm. The total length FL of the structure was 75 μm. The silicon nitride 160, the aluminum oxide 180, and the bottom P type polysilicon layer were rectangular and they spread underneath the entire tantalum nitride multi-finger structure.

The data points VBD_TANOSFE were obtained with the bottom polysilicon layer being patterned as 1000-finger structure as in FIG. 5B, with the dimensions as described above, except that FW=FS=0.07 μm. The overlying layers 150, 160, 180, 190 were rectangular layers overlying the whole 1000-finger structure.

The data points shown as “No Ox” in FIG. 5A are those for which the silicon nitride 160 was not oxidized at the edges. The remaining data points are those for which the silicon nitride 160 was oxidized to obtain the regions 160E (FIG. 4A). The oxidation was performed at 650° C. for 120 minutes.

Clearly, the rectangular capacitor (VBD_TANOS) has the largest area but the shortest peripheral boundary. This capacitor also has a large breakdown voltage (above 22V for most data points, and above 20V for all the data points with oxidized edges of SiRN 160). FIG. 5A thus indicates significant improvements that can be achieved if the leakage current is reduced at the periphery.

Table 1 below illustrates possible improvements in data retention. Table 1 shows test results performed on two wafers WF1, WF2 with test structures like those described above in connection with FIG. 5A. The charge trapping layer 160 had Si:N atomic ratio of 1:1. All the test structures were rectangular. The lateral dimensions W×L (width×length) were 10 μm×10 μm. In wafer WF1, the silicon nitride 160 was oxidized at the edges by a SELOX process after the capacitor structures were patterned.

After the test structures were fabricated, the wafers were baked, and the data retention was measured as a threshold voltage shift (Vt shift) after baking. Initially (before the baking) the test structures were programmed to Vt=3V. Then each wafer was baked in nitrogen ambient for one hour at 200° C., and Vt was measured. The results are shown in the line “1 hour, 200° C.”. Then the wafers were baked for two more hours (for the total of three hours) in nitrogen ambient at 200° C. and Vt was measured again. The results are shown in the line “3 hours, 200° C.”. Clearly, the wafer WF1 (with the oxidized silicon nitride 160) had a smaller Vt shift and hence better retention.

TABLE 1

| Baking Time | Vt (V) | Wafer WF1 | Wafer WF2 |
|---|---|---|---|
| 0 (initial) | Initial Vt | 3 V | 3 V |
| 1 hour, 200° C. | Vt drop | −0.5 V | −1.1 V |
| 3 hours, 200° C. | Vt drop | −0.6 V | −1.2 V |

Some embodiments of the present invention provide a method for manufacturing an integrated circuit comprising a nonvolatile memory cell, the memory cell comprising: a charge trapping region which is a dielectric region; and a conductive gate insulated from the charge trapping region by a first dielectric (e.g. by 180); the method comprising: (a) forming (i) charge trapping dielectric for the charge trapping region, (ii) the first dielectric, and (iii) a conductor for the conductive gate, wherein the charge trapping dielectric has an edge adjacent to an edge of the first dielectric; and then (b) oxidizing the charge trapping dielectric at said edge of the charge trapping dielectric to form an oxidized region (e.g. 160E) in the charge trapping dielectric, the oxidized region extending from said edge of the charge trapping dielectric by at least 4 nm.

In some embodiments, the charge trapping dielectric comprises silicon rich silicon nitride. Further, at least one of (i), (ii), (iii) is true, wherein: (i) throughout the oxidized region of the charge trapping dielectric, an atomic oxygen concentration is more than 30%; (ii) throughout the oxidized region of the charge trapping dielectric, the atomic nitrogen concentration is less than 30%; (iii) operation (b) increases an effective oxide thickness of the charge trapping dielectric by 3 nm.

In some embodiments, operation (a) comprises patterning the first dielectric by an etch which etches the first dielectric to form said edge of the first dielectric. Note for example the etch of aluminum oxide 180 described above in connection with FIG. 3A. The etch may reduce the resistivity of the first dielectric at the edge of the first dielectric to make the first dielectric leakier at the edge.

In some embodiments, the method further comprises, before operation (a), forming a second dielectric (e.g. tunnel dielectric 150) to insulate the charge-trapping dielectric from the memory cell's active area located in a semiconductor region.

In some embodiments, the oxidized region has a lower density of charge trapping sites than another region of the charge trapping dielectric farther away from said edge of the charge trapping dielectric. For example, edge regions 160E may have a lower density of charge trapping sites than the charge trapping dielectric 160 between the regions 160E.

In some embodiments, the oxidized region has a higher density of charge trapping sites than the second dielectric. For example, edge regions 160E may have a higher density of charge trapping sites than tunnel dielectric 150.

The invention is not limited to the embodiments described above. Other embodiments and variations are within the scope of the invention, as defined by the appended claims.

1. A method for manufacturing an integrated circuit comprising a nonvolatile memory cell, the memory cell comprising:
a charge trapping region which is a dielectric region; and
a conductive gate insulated from the charge trapping region by a first dielectric;
the method comprising:
(a) forming (i) charge trapping dielectric for the charge trapping region, (ii) the first dielectric, and (iii) a conductor for the conductive gate, wherein the charge trapping dielectric has an edge adjacent to an edge of the first dielectric; and then
(b) oxidizing the charge trapping dielectric at said edge of the charge trapping dielectric to form an oxidized region in the charge trapping dielectric, the oxidized region extending from said edge of the charge trapping dielectric by at least 4 nm.

2. The method of claim 1 wherein the charge trapping dielectric comprises silicon rich silicon nitride.

3. The method of claim 2 wherein at least one of (i), (ii), (iii) is true, wherein:
(i) throughout the oxidized region of the charge trapping dielectric, an atomic oxygen concentration is more than 30%;
(ii) throughout the oxidized region of the charge trapping dielectric, the atomic nitrogen concentration is less than 30%;
(iii) operation (b) increases an effective oxide thickness of the charge trapping dielectric by 3 nm.

4. The method of claim 1 wherein the first dielectric comprises aluminum oxide.

5. The method of claim 1 wherein operation (a) comprises patterning the first dielectric by an etch which etches the first dielectric to form said edge of the first dielectric.

6. The method of claim 1 further comprising, before operation (a), forming a second dielectric to insulate the charge-trapping dielectric from the memory cell's active area located in a semiconductor region.

7. The nonvolatile memory cell of claim 1 wherein the oxidized region has a lower density of charge trapping sites than another region of the charge trapping dielectric farther away from said edge of the charge trapping dielectric.

8. The nonvolatile memory cell of claim 7 further comprising, before operation (a), forming a second dielectric to insulate the charge-trapping dielectric from the memory cell's active area located in a semiconductor region, wherein the oxidized region has a higher density of charge trapping sites than the second dielectric.

9. A nonvolatile memory cell comprising:
an active area in a semiconductor region;
a charge trapping region which is a dielectric region insulated from the active area;
a first dielectric; and
a conductive gate insulated from the charge trapping region by the first dielectric;
wherein the charge trapping region has an edge adjacent to an edge of the first dielectric; and
the charge trapping region comprises an oxidized edge region extending from said edge of the charge trapping dielectric by at least 4 nm.

10. The nonvolatile memory cell of claim 9 wherein the charge trapping region comprises silicon rich silicon nitride.

11. The nonvolatile memory cell of claim 10 wherein at least one of (i), (ii), (iii) is true, wherein:
(i) throughout the oxidized edge region of the charge trapping dielectric, an atomic oxygen concentration is more than 30%;
(ii) throughout the oxidized edge region of the charge trapping dielectric, the atomic nitrogen concentration is less than 30%;
(iii) the oxidized edge region of the charge trapping dielectric increases an effective oxide thickness of the charge trapping dielectric by 3 nm.

12. The nonvolatile memory cell of claim 9 wherein the first dielectric comprises aluminum oxide.

13. The nonvolatile memory cell of claim 9 wherein the oxidized edge region has a lower density of charge trapping sites than another region of the charge trapping dielectric farther away from said edge of the charge trapping dielectric.

14. The nonvolatile memory cell of claim 13 further comprising a second dielectric between the charge trapping region and the active area, wherein the oxidized edge region has a higher density of charge trapping sites than the second dielectric.

15. A nonvolatile memory cell comprising:
an active area in a semiconductor region;
a charge trapping region which is a dielectric region insulated from the active area;
a first dielectric; and
a conductive gate insulated from the charge trapping region by the first dielectric;
wherein the charge trapping region has an edge adjacent to an edge of the first dielectric; and
the charge trapping region comprises a modified edge region extending from said edge of the charge trapping dielectric by at least 4 nm, wherein the modified edge region has a lower density of charge trapping sites than the charge trapping dielectric's other region farther away from said edge of the charge trapping region.

16. The nonvolatile memory cell of claim 15 further comprising a second dielectric between the charge trapping region and the active area, wherein the modified edge region has a higher density of charge trapping sites than the second dielectric.

17. The nonvolatile memory cell of claim 15 wherein the charge trapping region comprises silicon rich silicon nitride.

18. The nonvolatile memory cell of claim 17 wherein at least one of (i), (ii), (iii) is true, wherein:
(i) throughout the modified edge region, an atomic oxygen concentration is more than 30%;
(ii) throughout the modified edge region, the atomic nitrogen concentration is less than 30%;
(iii) the modified edge region increases an effective oxide thickness of the charge trapping dielectric by 3 nm.

19. The nonvolatile memory cell of claim 15 wherein the first dielectric comprises aluminum oxide.
